(19) United States
(12) Patent Application Publication
(10) Pub. No.: US 2010/0044748 A1
(43) Pub. Date: Feb. 25, 2010

(54) ELECTROSTATIC DISCHARGE PROTECTION DEVICE

(76) Inventors: Ta-Cheng Lin, Hsin-Chu City (TW); Te-Chang Wu, Hsinchu City (TW); Yu-Ming Sun, Taoyuan County (TW); Maung-Wai Lin, Taipei County (TW)

Correspondence Address: NORTH AMERICA INTELLECTUAL PROPERTY CORPORATION, P.O. BOX 506, MERRIFIELD, VA, 22116, US

(21) Appl. No.: 12/193,754

(22) Filed: Aug. 19, 2008

(51) Int. Cl. H01L 23/62

(52) U.S. Cl. 257/124; 257/E27.014

(57) ABSTRACT

An ESD protection device includes a p-well with first protrudent portions, an N-well with second protrudent portions, a P-well/N-well boundary, a PMOS transistor disposed in the N-well, an NMOS transistor disposed in the P-well, first P+ diffusion regions in the first protrudent portions, first N+ diffusion regions in the second protrudent portions, second P+ diffusion regions disposed between the PMOS transistor and the second protrudent portions, second N+ diffusion regions disposed between the NMOS transistor and the first protrudent portions, third P+ diffusion regions disposed between the NMOS transistor, the boundary, and two adjacent second P+ diffusion regions, and third N+ diffusion regions disposed between the PMOS transistor, the boundary, and two adjacent second N+ diffusion regions, wherein the first and second protrudent portions are interlacedly arranged at the boundary.

### BACKGROUND OF THE INVENTION

1. Field of the Invention

The present invention relates to an electrostatic discharge (ESD) protection device, and more particularly, to an ESD protection device having a P-type metal-oxide semiconductor (PMOS) transistor, an N-type metal-oxide semiconductor (NMOS) transistor, and two parasitic silicon controlled rectifier (SCR) elements.

2. Description of the Prior Art

ESD usually occurs in semiconductor devices. The ESD phenomenon occurs when excess charges are transmitted from the input/output (I/O) pin to the integrated circuit too quickly, which damages the internal circuit. In order to solve such a problem, manufacturers normally build an ESD protection device between the internal circuit and the I/O pin. The ESD protection device is initiated before the pulse of ESD enters the internal circuit for discharging the excess charges, and thus ESD-related damage is decreased.

Referring to FIG. 1, FIG. 1 is an equivalent circuit diagram of an ESD protection device 10 according to the prior art. The prior-art ESD protection device 10 is disposed between the bonding pad 12 and the internal circuit 14, and has a PMOS transistor 16 and an NMOS transistor 18. The source of the PMOS transistor 16 and the drain of the NMOS transistor 18 are electrically connected with each other and connected to the internal circuit 14 and the bonding pad 12 via a conducting wire 20. The source of the PMOS transistor 16 is connected to both the gate itself and a first power terminal VDD, such as a power supply terminal. The source of the NMOS transistor 18 is connected to both the gate itself and a second power terminal VSS, such as a grounded terminal. In addition, a first parasitic diode 22 is formed by the PMOS transistor 16 and a second parasitic diode 24 is formed by the NMOS transistor 18. When an ESD voltage is applied on the ESD protection device 10, across any two of the power terminal VDD, the bonding pad 12, and the power terminal VSS to produce ESD current, the ESD current is quickly discharged through the turned-on first parasitic diode 22, the turned-on second parasitic diode 24, the snapback breakdown of PMOS transistor 16, or the snapback breakdown of NMOS transistor 18.

With reference to FIG. 2, FIG. 2 is a top-view schematic diagram of the ESD protection device 10 shown in FIG. 1. The ESD protection device 10 is disposed on a P-type substrate 26, including a first N-well 28. The PMOS transistor 16 is disposed in the first N-well 28, and has a doped polysilicon layer 30 serving as at least a gate of the PMOS transistor 16, pluralities of first P+ diffusion regions 32 serving as the source/drains, and a first N+ diffusion region 36 surrounding the first P+ diffusion regions 32, wherein at least a drain or the first P+ diffusion regions 32 of the PMOS transistor 16 is electrically connected to the first power terminal VDD. The NMOS transistor 18 is disposed on the surface of the P-type substrate 26 at a side of the PMOS transistor 16 and the first N-well 28. The NMOS transistor 18 includes a doped polysilicon layer 34 serving at least a gate, pluralities of second N+ diffusion regions 38 serving as source/drains, and a second P+ diffusion region 40 surrounding the second N+ diffusion regions 38. At least one second N+ diffusion region 38 is electrically connected to the second power terminal VSS. In addition, in order to prevent the latch-up state of the NMOS transistor 18 and the PMOS transistor 16 from occurring, the ESD protection device 10 further comprises a double guard-ring 42 positioned between the NMOS transistor 18 and the PMOS transistor 16. The double guard-ring 42 includes a P+ guard ring 44 and an N+ guard ring 46 contiguous with each other, wherein the P+ guard ring 44 is disposed on the surface of a portion of the P-type substrate 26 (or a P-well) and adjacent to the PMOS transistor 16, and the N+ guard ring 46 is disposed in a second N-well 48, between the P+ guard ring 44 and the NMOS transistor 18.

Referring to FIG. 1 again, generally, the discharge path of the ESD protection device 10 includes four modes, such as a positive-to-VSS (PS) mode, a negative-to-VSS (NS) mode, a positive-to-VDD (PD) mode, and a negative-to-VDD (ND) mode. Under the PD and NS modes, the parasitic first and second diodes 22, 24 at the first P+ diffusion region 32/N-well 28 and the second N+ diffusion region 38/P-well (26) of the drains of the PMOS transistor 16 and NMOS transistor 18 are used to provide the ESD protection function. On the other hand, in the ND and PS modes, the parasitic bipolar transistors formed by the sources, drain, and the first N-well 28 or the P-type substrate 26 are used for protecting the internal circuit 14. However, the turned-on voltages of the parasitic bipolar transistors are high, and the gate oxide layer of an NMOS or PMOS transistor is becoming thinner with the continuing scaling-down of semiconductor integrated circuit (IC) device dimensions, thus the breakdown voltages of the gate oxide layer will become smaller, resulting in that the gate oxide layer easily burns out due to a high ESD current such that the prior-art ESD protection device 10 loses its protection function.

As a result, how to provide an effective ESD protection device as the process scale and device spaces of ICs are continuously reduced is still one of the important issues to the manufacturers.

### SUMMARY OF THE INVENTION

It is one of the primary objectives of the claimed invention to provide an ESD protection device having a PMOS transistor, an NMOS transistor, and two SCR elements to solve the above-mentioned problem that the prior-art ESD protection device may easily fail when the integration of IC becomes greater and greater.

According to the claimed invention, the present invention provides an ESD protection device disposed on a substrate and electrically connected to a bonding pad. The claimed invention ESD protection device comprises a P-well and an N-well contiguously disposed on the substrate. The P-well and the N-well comprises a plurality of first protrudent portions and a plurality of second protrudent portions respectively, wherein the first protrudent portions and the second protrudent portions are arranged interlacedly at a boundary of the P-well and the N-well. The ESD protection device further comprises a PMOS transistor disposed in the N-well, an NMOS transistor disposed in the P-well, a plurality of first P+ diffusion regions disposed in each first protrudent portion respectively, a plurality of first N+ diffusion regions disposed in each second protrudent portion respectively, a plurality of second P+ diffusion regions disposed between the PMOS transistor and the second protrudent portions, a plurality of second N+ diffusion regions disposed between the NMOS transistor and the first protrudent portions, a plurality of third P+ diffusion regions disposed between the PMOS transistor, the boundary, and the adjacent second P+ diffusion regions, and a plurality of third N+ diffusion regions disposed between the NMOS transistor, the boundary, and the adjacent second N+ diffusion regions. The third P+ diffusion regions are electrically connected to the bonding pad, the second P+ diffusion regions are electrically connected to a first power terminal VDD, the second N+ diffusion regions are electrically connected to a second power terminal VSS, and the third N+ diffusion regions are electrically connected to the bonding pad.

According to the present invention, an ESD protection device is further provided, which is electrically connected to a bonding pad. The claimed invention comprises a P-well and an N-well contiguously disposed on a surface of the substrate, wherein the P-well and the N-well respectively has a plurality of first protrudent portions and a plurality of second protrudent portions interlacedly arranged at a boundary of the P-well and the N-well. The claimed invention ESD protection device further comprises a PMOS transistor disposed in the N-well, an NMOS transistor disposed in the P-well, a plurality of first P+ diffusion regions respectively disposed in each second protrudent portion, a plurality of first N+ diffusion regions respectively disposed in each first protrudent portion, a plurality of second P+ diffusion regions disposed in the N-well, between the PMOS transistor and the boundary, and a plurality of second N+ diffusion regions disposed in the P-well, between the NMOS transistor and the boundary. The boundary is positioned between the second N+ diffusion regions and the first P+ diffusion regions and between the second P+ diffusion regions and the first N+ diffusion regions. The N-well, the P-well, each first P+ diffusion region and its adjacent second N+ diffusion region compose a first SCR element, and the N-well, the P-well, each second P+ diffusion region, and its adjacent first N+ diffusion region compose a second SCR element.

According to the claimed invention, an ESD protection device is even further provided. The ESD protection device is disposed on a surface of the substrate and electrically connected to a bonding pad, comprising a P-well and an N-well contiguously disposed on the surface of the substrate, a PMOS transistor disposed in the N-well, an NMOS transistor disposed in the P-well, a plurality of first P+ diffusion regions and a plurality of second P+ diffusion regions interlacedly arranged in the N-well, between the PMOS transistor and the boundary of the N-well/P-well, and a plurality of first N+ diffusion regions and a plurality of second N+ diffusion regions interlacedly arranged in the P-well, between the NMOS transistor and the boundary of the N-well/P-well. Each of the first and second N+ diffusion regions corresponds to one of the second P+ diffusion regions and one of the first P+ diffusion regions respectively. The N-well, the P-well, each first P+ diffusion region, and its corresponding second N+ diffusion region compose a first SCR element, and the N-well, the P-well, each second P+ diffusion region, and its corresponding first N+ diffusion region compose a second SCR element.

It is an advantage of the present invention ESD protection device that the claimed ESD protection device includes the first and second SCR elements disposed in the space where the double guard-rings are used to be disposed according to the conventional ESD protection device. Therefore, the dimension of the claimed invention ESD protection device does not have to be increased, and an effective protection function of the PS and ND ESD modes can be provided.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an equivalent circuit diagram of an ESD protection device according to the prior art.

FIG. 2 is a top-view schematic diagram of the ESD protection device shown in FIG. 1.

FIG. 3 is an equivalent circuit diagram of an ESD protection device according to a first embodiment of the present invention.

FIG. 4 is a top-view schematic diagram of the ESD protection device shown in FIG. 3 according to the present invention.

FIG. 5 is a sectional view of the ESD protection device shown in FIG. 4 along line 5-5′.

FIG. 6 is a sectional view of the ESD protection device shown in FIG. 4 along line 6-6′.

FIG. 7 is a top-view schematic diagram of an ESD protection device according to a second embodiment of the present invention.

FIG. 8 is an equivalent circuit diagram of an ESD protection device shown in FIG. 7.

FIG. 9 is an equivalent circuit diagram of an ESD protection device according to a third embodiment of the present invention.

FIG. 10 is a top-view schematic diagram of an ESD protection device according to a fourth embodiment of the present invention.

FIG. 11 is a top-view schematic diagram of an ESD protection device according to a fifth embodiment of the present invention.

FIG. 12 is a top-view schematic diagram of an ESD protection device according to a sixth embodiment of the present invention.

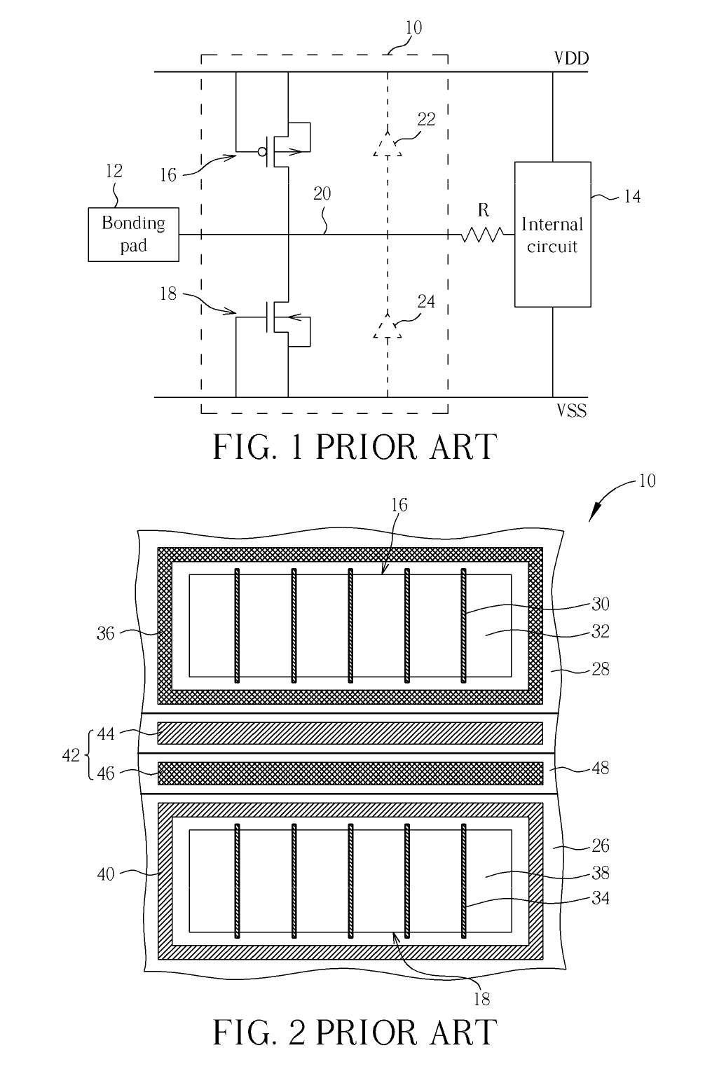

### DETAILED DESCRIPTION

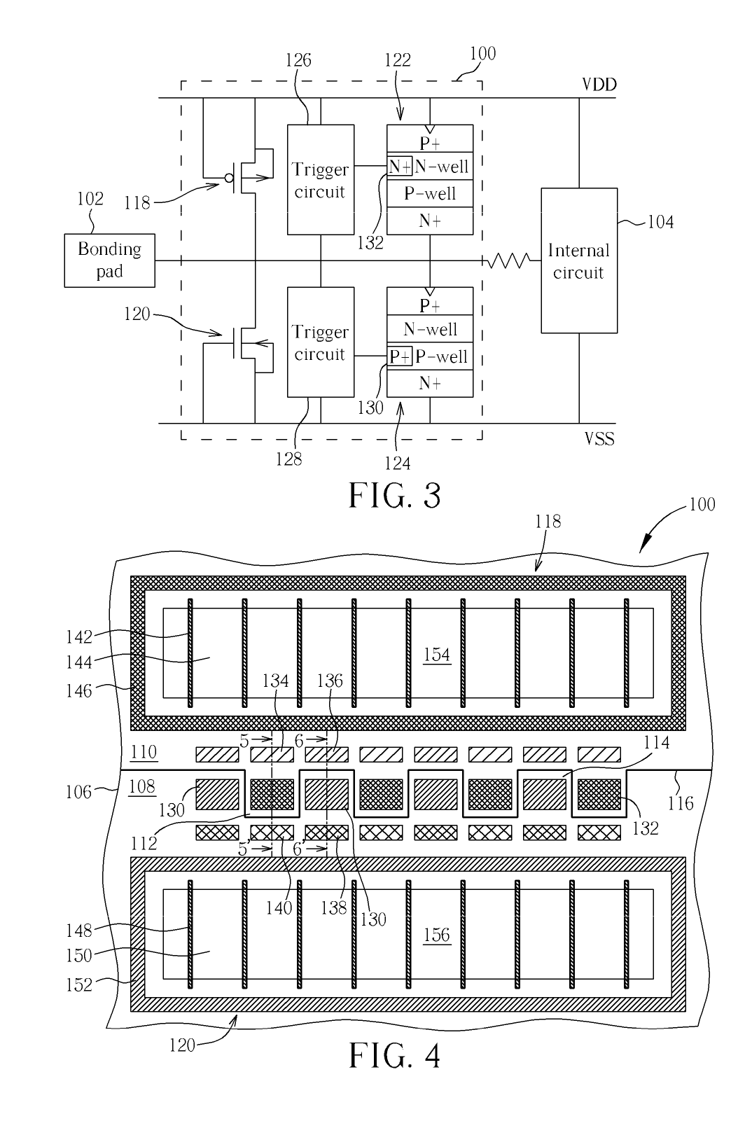

With reference to FIG. 3 and FIG. 4, FIG. 3 is an equivalent circuit diagram of an ESD protection device according to a first embodiment of the present invention, and FIG. 4 is a top-view schematic diagram of the ESD protection device shown in FIG. 3. The present invention ESD protection device 100 is electrically connected to a bonding pad 102 (such as an I/O pin) and an internal circuit 104, comprising a PMOS transistor 118, an NMOS transistor 120, a first SCR element 122, and a second SCR element 124. The source of the PMOS transistor 118 and the drain of the NMOS transistor 120 are electrically connected to the internal circuit 104 and the bonding pad 102 respectively, and the drain of the PMOS transistor 118 and the anode of the first SCR element 122 are electrically connected to a first power terminal VDD, which may be a power supply terminal. The source of the NMOS transistor 120 and the cathode of the second SCR element 124 are electrically connected to the second power terminal VSS, which may be grounded. The cathode of the first SCR element 122 and the anode of the second SCR element 124 are electrically connected to the bonding pad 102 and the internal circuit 104. In addition, the first SCR element 122 and the second SCR element 124 respectively have a trigger node, the first N+ diffusion region 132 and the first P+ diffusion region 130, which are electrically connected to the first trigger circuit 126 and the second trigger circuit 128 respectively. The amount of trigger circuit is not limited to the amount that is disclosed; the present embodiment can alternatively dispose the two trigger circuits 126, 128, and separately provide a trigger current to quickly turn on the ESD protection device 100. In other embodiments, the first N+ diffusion region 132 and the first P+ diffusion region 130 can also be coupled to the same trigger circuit (not shown).

The top-view schematic diagram of the present invention ESD protection device 100 is shown in FIG. 4. The ESD protection device 100 is disposed on a substrate 106, such as a P-type silicon substrate, and comprises a P-well 108 and an N-well 110 contiguously disposed, wherein the P-well 108 may be a portion of the substrate 106. The P-well 108 and the N-well 110 has a boundary 116, and the P-well 108 and the N-well 110 respectively comprises a plurality of first protrudent portions 114 and a plurality of second protrudent portions 112, interlacedly arranged at the boundary 116 of the P-well 108 and the N-well 110. The PMOS transistor 118 and the NMOS transistor 120 are respectively disposed in the N-well 110 and the P-well 108. Between the PMOS transistor 118 and the NMOS transistor 120, a plurality of P+ diffusion regions and N+ diffusion regions are disposed to form the above-mentioned first SCR element 122 and second SCR element 124. As shown in FIG. 4, the ESD protection device 100 comprises a plurality of first P+ diffusion regions 130 disposed in one of the first protrudent portions 114 respectively, a plurality of first N+ diffusion regions 132 disposed in one of the second protrudent portions 112, a plurality of second P+ diffusion regions 134 and third P+ diffusion regions 136 disposed in the N-well 110, and a plurality of second N+ diffusion regions 138 and third N+ diffusion regions 140 disposed in the P-well 108. The second P+ diffusion regions 134 are positioned between the PMOS transistor 118 and the second protrudent portions 112, electrically connected to the first power terminal VDD. The third P+ diffusion regions 136 are disposed adjacently to the second P+ diffusion regions 134, and are disposed in between the PMOS transistor 118 and the boundary 116, and are electrically connected to the bonding pad 102. The second N+ diffusion regions 138 are disposed between the NMOS transistor 120 and the first protrudent portions 114 and are electrically connected to the second power terminal VSS. The third N+ diffusion regions 140 are disposed adjacently to the second N+ diffusion regions 138, and are disposed in between the NMOS transistor 120 and boundary 116, and any two adjacent second N+ diffusion regions 138, and are electrically connected to the bonding pad 102. In addition, the P-well 108, each of the second P+ diffusion regions 134, and its adjacent second protrudent portion 112, first N+ diffusion region 132 and third N+ diffusion region 140 compose the first SCR element 122. The P-well 108, each of the third P+ diffusion regions 136, and its adjacent first protrudent portion 114, first P+ diffusion region 130, and second N+ diffusion region 138 form the second SCR element 124.

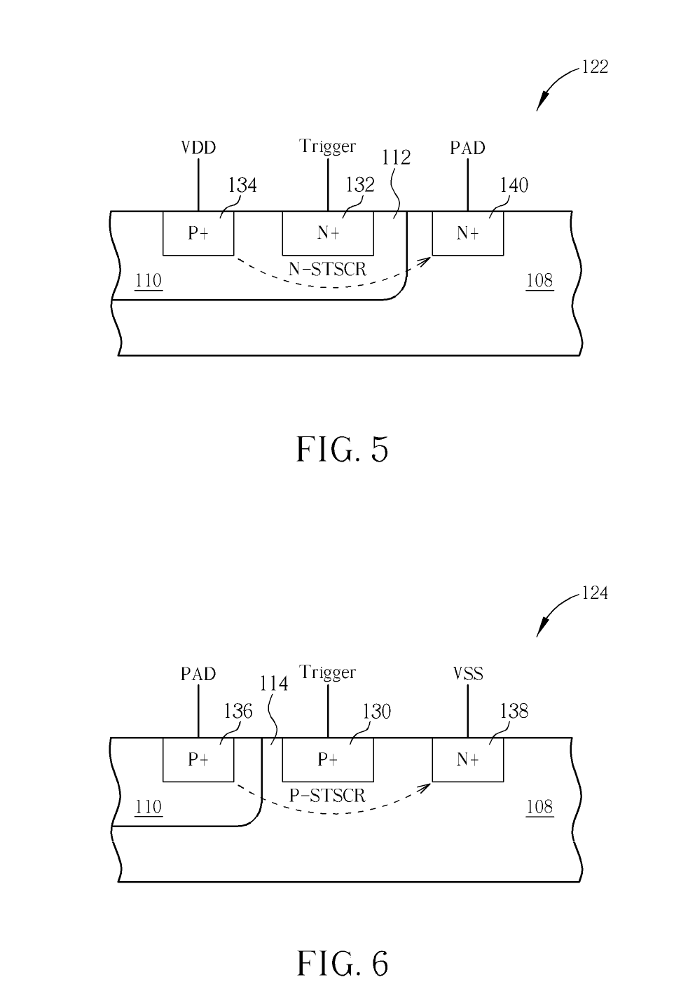

Referring to FIG. 5, FIG. 5 is a sectional view of the ESD protection device 100 shown in FIG. 4 along line 5-5′. Along the section line 5-5′, the adjacent second P+ diffusion regions 134, the second protrudent portions 112 of the N-well 110, the first N+ diffusion regions 132, the P-well 108, and the third N+ diffusion region 140 form a lateral N-type substrate-triggered SCR (N-STSCR) element respectively. Therefore, the ESD protection device 100 comprises a plurality of N-STSCR elements disposed in parallel connection, between the PMOS transistor 118 and the NMOS transistor 120, which may be represented by the first SCR element 122 shown in FIG. 3. Each second P+ diffusion region 134 serves as the anode of the first SCR element 122, each third N+ diffusion region 140 serves as the cathode of the first SCR element 122, and each first N+ diffusion region 132 serves as the trigger node of the first SCR element 122, which may be electrically connected to the first trigger circuit 126. Under the ND mode, when the ESD current provides a negative voltage from the bonding pad 102 to the first power terminal VDD, the trigger node of the first N+ diffusion regions 132 lowers the potential of the N-well 110 to forward bias to the boundary of the N-well 110/the second P+ diffusion regions 134, such that the first SCR element 122 is conducted to provide a low-resistance path to discharge the ESD current form the anode to the cathode of the first SCR element 122.

Please refer to FIG. 6, which is a sectional view of the ESD protection device 100 shown in FIG. 4 along line 6-6′. Similarly, along the direction of the section line 6-6′, the adjacent third P+ diffusion regions 136, the N-well 110, the first protrudent portions 114 of the P-well 108, the first P+ diffusion regions 130, and the second N+ diffusion regions 138 compose a lateral P-type substrate-triggered SCR (P-STSCR) element respectively, disposed in parallel connection to form the second SCR element 124 shown in FIG. 3. Each third P+ diffusion regions 136 and second N+ diffusion regions 138 respectively serve as the anode and cathode of the P-STSCR element. The first P+ diffusion regions 130 serve as the trigger node to be electrically connected to the second trigger circuit 128. Under the PS mode, the ESD current provides a positive voltage to the second power terminal VSS from the bonding pad 102, the trigger node of the first P+ diffusion regions 130 will raise the potential of the P-well 108 to forward bias to the boundary of the P-well 108/the second N+ diffusion regions 138, such that the P-STSCR elements are conducted to provide a low-resistance path for discharging the ESD current.

In addition, as shown in FIG. 4, the PMOS transistor 118 comprises a plurality of gates 142, a plurality of source/drains 144 disposed at two sides of the gate 142, and a fourth N+ diffusion region 146 disposed in the N-well 110. The fourth N+ diffusion region 146 serves as a well pick-up of the PMOS transistor 118, surrounding the gates 142 and the source/drains 144 and without contacting the gates 142 and the source/drains 144. The gates 142 may comprise doped polysilicon materials and are disposed on the N-well 110, and the source/drains 144 comprise a plurality of fifth P+ diffusion regions 154 disposed on the surface of the substrate 106. On the other hand, the NMOS transistor 120 comprises a plurality of gates 148, a plurality of source/drains 150 disposed at two sides of the gates 148, and a fourth P+ diffusion region 152 disposed in the P-well 108 to serve as a well pick-up of the NMOS transistor 120, surrounding the gates 148 and the source/drains 150 and without contacting the gates 148 and the source/drains 150. The gates 148 are preferably composed of doped polysilicon materials, and the source/drains 150 may be formed with a plurality of fifth N+ diffusion regions 156.

It should be noted that the present invention ESD protection device 100 has a saw-toothed boundary 116 of the P-well 108 and the N-well 110. The second and third P+ diffusion regions 134, 136 are interlacedly arranged in the N-well 110, electrically connected to the first power terminal VDD and the bonding pad 102 respectively, while the second and third N+ diffusion regions 138, 140 are interlacedly arranged in the P-well 108 and electrically connected to the second power terminal VSS and the bonding pad 102 respectively. As a result, a plurality of parasitic N-STSCR elements in parallel connection are formed between the bonding pad 102 and the first power terminal VDD, and a plurality of parasitic P-STSCR elements in parallel connection are formed between the bonding pad 102 and the second power terminal VSS. Therefore, the double guard-ring in the conventional ESD protection device is omitted, whose space is utilized to dispose the N-STSCR and P-STSCR elements according to the present invention ESD protection device 100. It is effective to raise the holding voltages of the N-STSCR and P-STSCR elements to make them be larger than the first power terminal VDD for preventing the latch-up state and the ESD protection device 100 from failing. The method of increasing the holding voltages of the N-STSCR and the P-STSCR elements may be practiced by providing a diode in series connection or increasing the distance between the third P+ diffusion regions 140 and the second N+ diffusion regions 138.

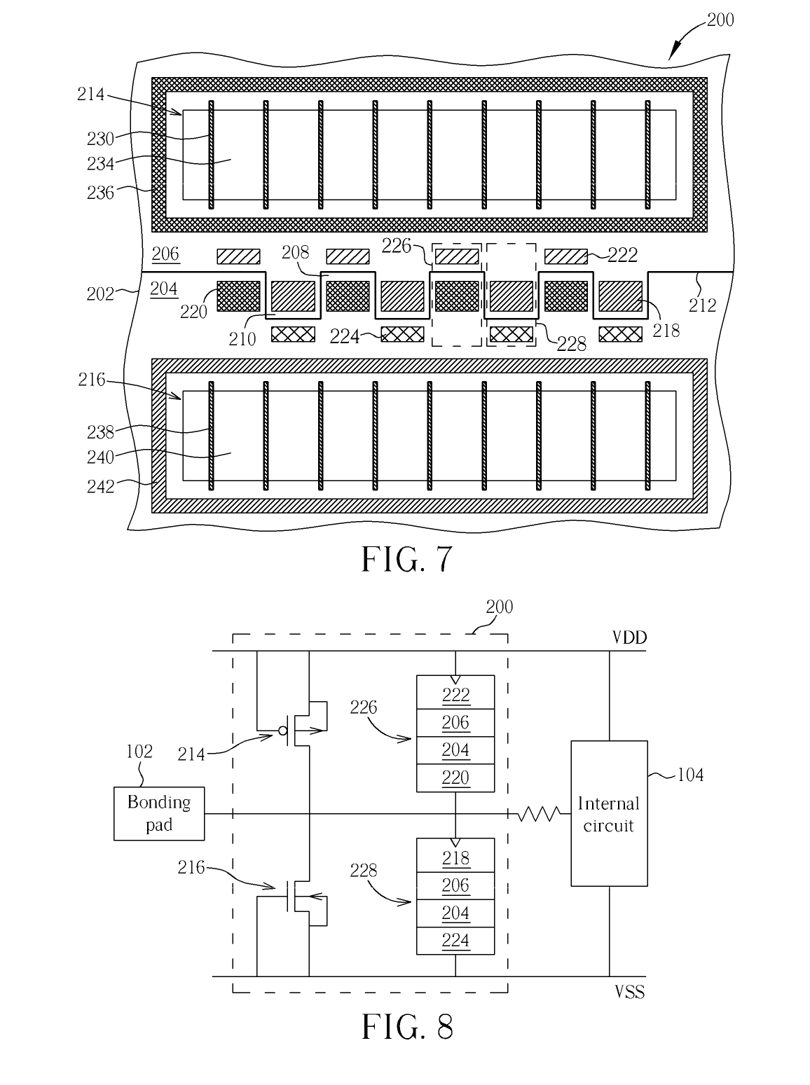

FIG. 7 is a top-view schematic diagram of an ESD protection device 200 according to a second embodiment of the present invention. The present invention ESD protection device 200 is disposed on a substrate 202, such as a P-type silicon substrate, and electrically connected to a bonding pad 102 and an internal circuit 104 as shown in FIG. 3. The ESD protection device 200 comprises a P-well 204 and an N-well 206 contiguously disposed on the surface of a substrate 202, wherein the P-well 202 and the N-well 204 respectively have a plurality of first protrudent portions 208 and a plurality of second protrudent portions 210, interlacedly arranged at a boundary 212 of the P-well 204 and N-well 206. The ESD protection device 200 further comprises a PMOS transistor 214 disposed in the N-well 206, an NMOS transistor 216 disposed in the P-well 204, a plurality of first P+ diffusion regions 218 disposed in each second protrudent portions 210 respectively, a plurality of first N+ diffusion regions 220 disposed in each first protrudent portions 208 respectively, a plurality of second P+ diffusion regions 222 disposed in the N-well 206 between the PMOS transistor 214 and the boundary 212, and a plurality of second N+ diffusion regions 224 disposed in the P-well 204 between the NMOS transistor 216 and the boundary 212. In addition, the boundary 212 is positioned between the second P+ diffusion regions 222 and the first N+ diffusion regions 220 and between the second N+ diffusion regions 224 and the first P+ diffusion regions 218.

In this embodiment, the first P+ diffusion regions 218 and the first N+ diffusion regions 220 are electrically connected to the bonding pad 102, the second P+ diffusion regions 222 are electrically connected to a first power terminal VDD, and the second N+ diffusion regions 224 are electrically connected to a second power terminal VSS. Accordingly, along the direction from the PMOS transistor 214 to the NMOS transistor 216, the N-well 206, the first protrudent portion 208 of the P-well 204, each second P+ diffusion region 222, and its adjacent first N+ diffusion region 220 compose a first SCR element 226, while the second protrudent portion 210 of the N-well 206, the P-well 204, each first P+ diffusion region 218 and its adjacent second N+ diffusion region 224 compose a second SCR element 228. The equivalent circuit diagram of the present invention ESD protection device 200 is shown in FIG. 8. The second P+ diffusion regions 222 and the first N+ diffusion regions 220 serve as the anode and cathode of the first SCR element 226 respectively, and the first P+ diffusion regions 218 and the second N+ diffusion regions 224 serve as the anode and cathode of the second SCR element 228.

In addition, as shown in FIG. 7, the PMOS transistor 214 comprises at least a gate 230 composed of doped polysilicon materials, a plurality of source/drains 234 including P+ diffusion regions, and a well pick-up 236 formed with an N+ diffusion region. The NMOS transistor 216 comprises at least a gate 238 composed of doped polysilicon materials, a plurality of source/drains 240 composed of N+ diffusion regions, and a well pick-up 242 including a P+ diffusion region.

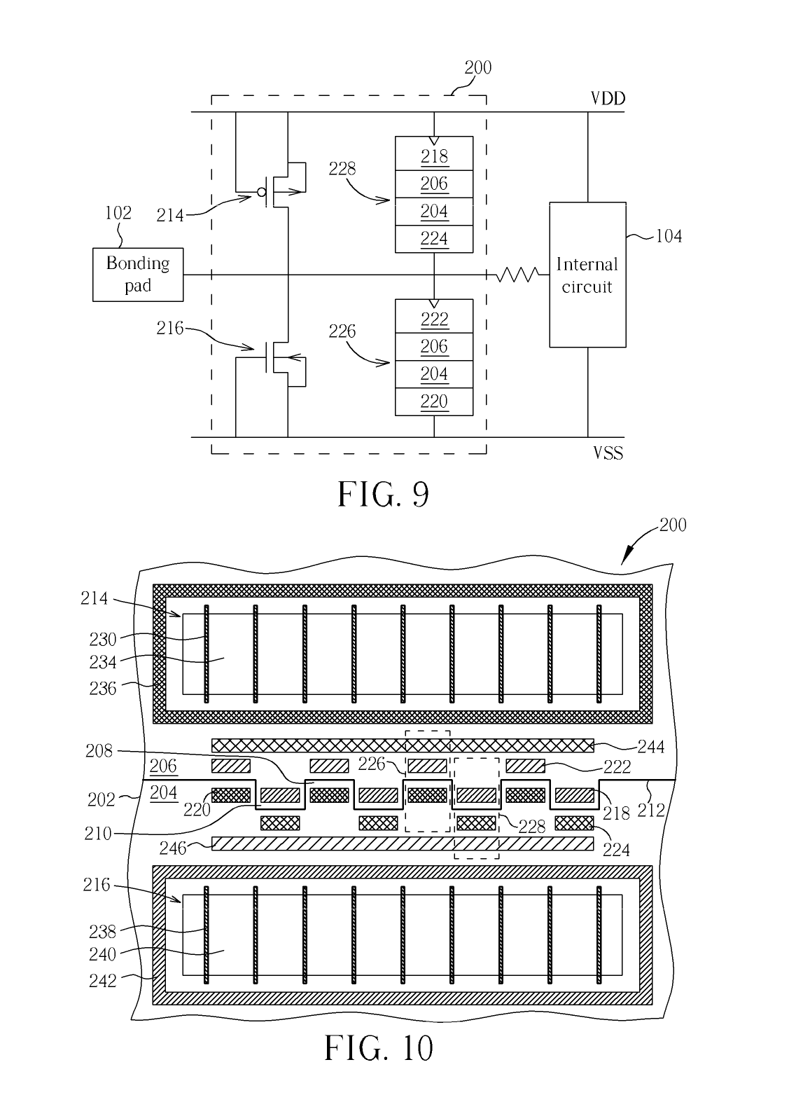

However, in other embodiments of the present invention, the electrical connection objects of the first P+ diffusion regions 218, the second P+ diffusion regions 222, the first N+ diffusion regions 220, and the second N+ diffusion regions 224 may be varies for adjusting the top-view arrangement of the first and the second SCR elements 226, 228. For example, according to a third embodiment of the present invention ESD protection device, the first P+ diffusion regions 218 and the second P+ diffusion regions 222 may be selectively electrically connected to the first power terminal VDD and the bonding pad 102 respectively, and the first N+ diffusion regions 220 and the second N+ diffusion regions 224 may be selectively electrically connected to the second power terminal VSS and the bonding pad 102 respectively. FIG. 9 is the equivalent circuit diagram of the ESD protection device of the third embodiment of the present invention. As shown in FIG. 9, the first P+ diffusion regions 218, the second N+ diffusion regions 224, the N-well 206, and the P-well 204 form the first SCR element 226. The second P+ diffusion regions 222, the adjacent first N+ diffusion regions 220, the N-well 206, and the P-well 204 form the second SCR element 228.

FIG. 10 is a top-view schematic diagram of an ESD protection device according to a fourth embodiment of the present invention, wherein the same elements of FIG. 10 are represented with the same numerals shown in FIG. 7. The main difference between this embodiment and the second embodiment of the present invention includes that the ESD protection device 200 further includes a first ion diffusion region 244 (such as a third N+ diffusion region) and a second ion diffusion region 246 (such as a third P+ diffusion region) disposed in the N-well 206 and the P-well 204 respectively, wherein the first ion diffusion region 244 and the second ion diffusion region 246 are used as the trigger nodes of the first SCR element 226 and the second SCR element 228 respectively. As shown in FIG. 10, the first ion diffusion region 244 is disposed between the PMOS transistor 214 and the second P+ diffusion regions 222, and the second ion diffusion region 246 is disposed between the NMOS transistor 216 and the second N+ diffusion regions 224. The first ion diffusion region 244 and the second ion diffusion region 246 may be electrically connected to a trigger circuit (not shown) respectively so as to trigger the first and second SCR elements 226, 228.

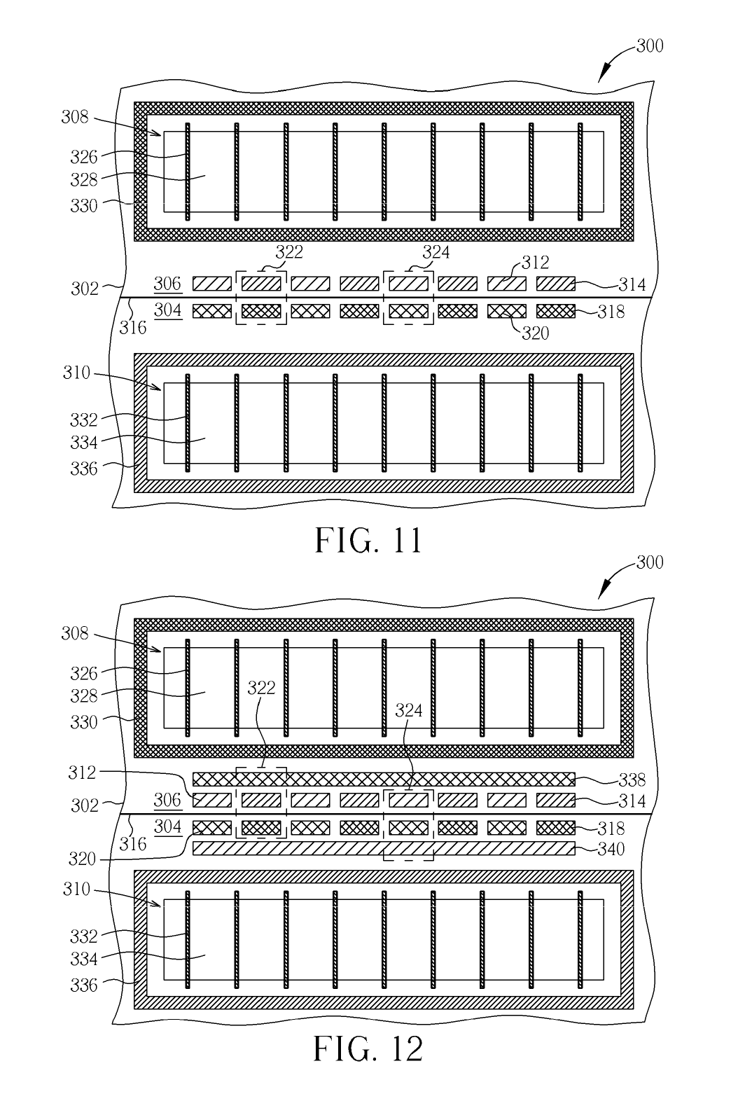

With reference to FIG. 11, FIG. 11 is a top-view schematic diagram of an ESD protection device 300 according to a fifth embodiment of the present invention. Similarly, the present invention ESD protection device 300 is electrically connected to a bonding pad 102 and an internal circuit 104 as shown in FIG. 3, and is disposed on a surface of a substrate 302. The ESD protection device 300 comprises a P-well 304 and an N-well 306 contiguously arranged on the surface of the substrate 302. The P-well 304 and the N-well 306 has a boundary 316. The substrate 302 may be a P-type silicon substrate, and the P-well 304 may be considered as a portion of the P-type silicon substrate. The ESD protection device 300 further comprises a PMOS transistor 308 disposed in the N-well 306, an NMOS transistor 310 disposed in the P-well 304, a plurality of first P+ diffusion regions 312, a plurality of second P+ diffusion regions 314, a plurality of first N+ diffusion regions 318 and a plurality of second N+ diffusion regions 320. In addition, the first P+ diffusion regions 312 are disposed between the PMOS transistor 308 and the boundary 316. The second P+ diffusion regions 314 are disposed adjacently to the first P+ diffusion regions 312, and in between the PMOS transistor 308 and the boundary 316. The first N+ diffusion regions 318 are disposed in between the NMOS transistor 310 and the boundary 316. The second N+ diffusion regions 320 are disposed adjacently to the first N+ diffusion regions 318, and in between the NMOS transistor 310 and the boundary 316. In other words, the first P+ diffusion regions 312 and the second P+ diffusion regions 314 are interlacedly arranged along the boundary 316 in the N-well 306, and the first N+ diffusion regions 318 and the second N+ diffusion regions 320 are interlacedly arranged along the boundary 316 in the P-well 304. Each of the first and second N+ diffusion regions 318, 320 corresponds to a second P+ diffusion region 314 and a first P+ diffusion region 312.

The first P+ diffusion regions 312 and the first N+ diffusion regions 318 are electrically connected to the bonding pad 102, the second P+ diffusion regions 314 are electrically connected to a first power terminal VDD, and the second N+ diffusion regions 320 are electrically connected to a second power terminal VSS. Accordingly, the N-well 306, the P-well 304, each second P+ diffusion region 314, and its corresponding first N+ diffusion region 318 compose a first SCR element 322, while the N-well 306, the P-well 304, each first P+ diffusion region 312, and its corresponding second N+ diffusion region 320 form a second SCR element 324. In addition, the PMOS transistor 308 comprises a plurality of gates 326, a plurality of source/drains 328, and a well pick-up 330, surrounding the gates 326 and the source/drains 328, and the NMOS transistor 310 comprises a plurality of gates 332, a plurality of source/drains 334, and a well pick-up 336, surrounding the gates 332 and the source/drains 334.

With reference to FIG. 12, FIG. 12 is a schematic diagram of an ESD protection device according to a sixth embodiment of the present invention. The numerals shown in FIG. 11 are used to represent the same elements in FIG. 12. The main difference between the fifth embodiment and the sixth embodiment of the present invention includes that the ESD protection device 300 of the sixth embodiment further comprises a first ion diffusion region 338 and a second ion diffusion region 340 serving as the trigger nodes of the first SCR element 322 and the second SCR element 324. The first ion diffusion region 338, such as a third N+ diffusion region, is disposed between the PMOS transistor 308 and the first and second P+ diffusion regions 312, 314 in the N-well 306. The second ion diffusion region 340, such as a third P+ diffusion region, is disposed between the NMOS transistor 310 and the first and second N+ diffusion regions 318, 320 in the P-well 304. In addition, the first and the second ion diffusion regions 338, 340 may be electrically connected to a trigger circuit (not shown) for triggering the first SCR element 322 and the second SCR element 324 respectively.

In contrast to the prior art, the present invention ESD protection device comprises a PMOS transistor, an NMOS transistor, and two parasitic SCR elements. Accordingly, the parasitic diodes of the PMOS and NMPS transistors are used for discharging the ESD current under the PD or NS modes. However, under the PS or ND modes, the SCR elements are used for providing the discharging path of the ESD current. In addition, according to the present invention, a plurality of N+ and P+ diffusion regions are positioned between the PMOS and NMOS transistors, which are electrically connected to the bonding pad, the first power terminal VDD, or the second power terminal VSS to form the SCR elements, replacing the double guard-rings in the conventional ESD protection device, such that no extra space is needed for disposing the SCR elements. Accordingly, effective discharging path of ND and PS mode can be provided by the SCR elements without increasing the area of the ESD protection device of the present invention. Furthermore, although the double guard-ring in the conventional ESD protection device are omitted by the present invention for setting the SCR elements, the latch-up state can be still avoided through controlling the holding voltages of the SCR elements to be larger than the first power terminal VDD.

Those skilled in the art will readily observe that numerous modifications and alterations of the device and method may be made while retaining the teachings of the invention.

What is claimed is:

1. An electrostatic discharge (ESD) protection device, disposed on a substrate and electrically connected to a bonding pad, comprising:
a P-well and an N-well contiguously disposed on the substrate, the P-well and the N-well having a plurality of first protrudent portions and a plurality of second protrudent portions respectively, and the first and second protrudent portions being interlacedly arranged at a boundary of the P-well and the N-well;
a P-type metal-oxide semiconductor (PMOS) transistor disposed in the N-well;
an N-type metal-oxide semiconductor (NMOS) transistor disposed in the P-well;
a plurality of first P+ diffusion regions positioned in each of the first protrudent portions respectively;
a plurality of first N+ diffusion regions positioned in each of the second protrudent portions respectively;
a plurality of second P+ diffusion regions, positioned between the PMOS transistor and the second protrudent portions and electrically connected to a first power terminal (VDD);
a plurality of second N+ diffusion regions, positioned between the NMOS transistor and the first protrudent portions and electrically connected to a second power terminal (VSS);
a plurality of third P+ diffusion regions, positioned between the PMOS transistor, the boundary, and any two of the adjacent second P+ diffusion regions, the third P+ diffusion regions being electrically connected to the bonding pad; and
a plurality of third N+ diffusion regions, positioned between the NMOS transistor, the boundary, and any two of the adjacent second N+ diffusion regions, the third N+ diffusion regions are electrically connected to the bonding pad.

2. The ESD protection device of claim 1, further comprising at least a first silicon controlled rectifier (SCR) element composed of the P-well, one of the second P+ diffusion regions, one of the second protrudent portions, one the first N+ diffusion regions, and one of the third N+ diffusion regions near the second P+ diffusion region.

3. The ESD protection device of claim 2, wherein the first N+ diffusion regions are electrically connected to a first trigger circuit.

4. The ESD protection device of claim 1, further comprising at least a second SCR element composed of the N-well, one of the third P+ diffusion regions, one of the first protrudent portions, one of the first P+ diffusion regions, and one of the second N+ diffusion regions near the third P+ diffusion region.

5. The ESD protection device of claim 4, wherein the first P+ diffusion regions are electrically connected to a second trigger circuit.

6. The ESD protection device of claim 1, wherein the second and third P+ diffusion regions are disposed in the N-well, the second and third N+ diffusion regions are disposed in the P-well.

7. The ESD protection device of claim 1, wherein the PMOS transistor comprises:
at least a gate;
at least a source and a drain, positioned at two sides of the gate; and
a fourth N+ diffusion region positioned in the N-well, surrounding the gate, the source, and the drain, without contacting the gate, the source, and the drain.

8. The ESD protection device of claim 1, wherein the NMOS transistor comprises:
at least a gate;
at least a source and a drain, positioned at two sides of the gate; and
a fourth P+ diffusion region positioned in the P-well, surrounding the gate, the source, and the drain, without contacting the gate, the source, and the drain.

9. An ESD protecting device, disposed on a substrate and electrically connected to a bonding pad, comprising:
a P-well and an N-well contiguously disposed on the substrate, the P-well and the N-well having a plurality of first protrudent portions and a plurality of second protrudent portions respectively, and the first protrudent portions and the second protrudent portions being arranged interlacedly at a boundary of the P-well and the N-well;
a PMOS transistor disposed in the N-well;
an NMOS transistor disposed in the P-well;
a plurality of first P+ diffusion regions disposed in each of the second protrudent portions respectively;
a plurality of first N+ diffusion regions disposed in each of the first protrudent portions respectively;
a plurality of second P+ diffusion regions disposed in the N-well, positioned between the PMOS transistor and the boundary, the boundary being positioned between the second P+ diffusion regions and the first N+ diffusion regions; and
a plurality of second N+ diffusion regions disposed in the P-well, positioned between the NMOS transistor and the boundary, the boundary being positioned between the second N+ diffusion regions and the first P+ diffusion regions;
wherein the N-well, the P-well, each of the second P+ diffusion regions, and the adjacent first N+ diffusion region compose a first SCR element, and the N-well, the P-well, each of the first P+ diffusion regions, and the adjacent the second N+ diffusion region compose a second SCR element.

10. The ESD protection device of claim 9, wherein the first P+ diffusion regions are electrically connected to the bonding pad, the second P+ diffusion regions are electrically connected to a first power terminal, the first N+ diffusion regions are electrically connected to the bonding pad, and the second N+ diffusion regions are electrically connected to a second power terminal.

11. The ESD protection device of claim 9, wherein the first P+ diffusion regions are electrically connected to a first power terminal, the second P+ diffusion regions are electrically connected to the bonding pad, the first N+ diffusion regions are electrically connected to a second power terminal, and the second N+ diffusion regions are electrically connected to the bonding pad.

12. The ESD protection device of claim 9, wherein the first SCR elements comprise at least a trigger node positioned in the N-well.

13. The ESD protection device of claim 12, wherein the trigger node further comprises at least a first ion diffusion region, positioned between the PMOS transistor and the second P+ diffusion regions.

14. The ESD protection device of claim 9, wherein the second SCR elements comprise at least a trigger node positioned in the P-well.

15. The ESD protection device of claim 14, wherein the trigger node further comprises at least a second ion diffusion region, positioned between the NMOS transistor and the second N+ diffusion regions.

16. An ESD protection device, disposed on the substrate and electrically connected to a bonding pad, comprising:
a P-well and an N-well contiguously disposed on the substrate, the P-well and the N-well having a boundary;
a PMOS transistor disposed in the N-well;
an NMOS transistor disposed in the P-well;
a plurality of first P+ diffusion regions and a plurality of second P+ diffusion regions disposed in the N-well between the PMOS transistor and the boundary, the first and the second P+ diffusion regions being interlacedly arranged along the boundary; and
a plurality of first N+ diffusion regions and a plurality of second N+ diffusion regions disposed in the P-well between the NMOS transistor and the boundary, the first and the second N+ diffusion regions being interlacedly arranged along the boundary, and each of the first and the second N+ diffusion regions corresponding to one of the second P+ diffusion regions and one of the first P+ diffusion regions respectively;
wherein the N-well, the P-well, each of the second P+ diffusion regions and the corresponding first N+ diffusion region compose a first SCR element, and the N-well, the P-well, each of the first P+ diffusion regions and the corresponding second N+ diffusion region compose a second SCR element.

17. The ESD protection device of claim 16, wherein the first P+ diffusion regions are electrically connected to the bonding pad, the second P+ diffusion regions are electrically connected to a first power terminal, the first N+ diffusion regions are electrically connected to the bonding pad, and the second N+ diffusion regions are electrically connected to a second power terminal.

18. The ESD protection device of claim 16, wherein the first SCR elements comprise at least a first trigger node, disposed in the N-well.

19. The ESD protection device of claim 18, wherein the first trigger node further comprises at least a first ion diffusion region, positioned between the PMOS transistor and the first and the second P+ diffusion regions.

20. The ESD protection device of claim 16, wherein the second SCR elements comprise at least a second trigger node, disposed in the P-well.

21. The ESD protection device of claim 20, wherein the second trigger node comprises at least a second ion diffusion region, positioned between the NMOS transistor and the first and the second N+ diffusion regions.
